(19) United States
(12) Patent Application Publication
(10) Pub. No.: US 2019/0066614 A1
(43) Pub. Date: Feb. 28, 2019

(54) ARRAY SUBSTRATE, METHOD FOR DRIVING THE SAME AND DISPLAY DEVICE

(71) Applicants: BOE Technology Group Co., Ltd., Beijing (CN); Chongqing BOE Optoelectronics Technology Co., Ltd., Chongqing (CN)

(72) Inventors: Xiuzhu Tang, Beijing (CN); Tae Yup Min, Beijing (CN); Heecheol Kim, Beijing (CN); Lijun Xiong, Beijing (CN); Zhihui Wang, Beijing (CN); Taoliang Tang, Beijing (CN); Changgong Zhu, Beijing (CN)

(21) Appl. No.: 16/013,009

(22) Filed: Jun. 20, 2018

(30) Foreign Application Priority Data
Aug. 23, 2017 (CN) 201710729162.2

(51) Int. Cl. G09G 3/36; H01L 27/12; G02F 1/1368; G02F 1/1345; G02F 1/1362

(52) U.S. Cl. CPC G09G 3/3659; G09G 3/3614; H01L 27/124; G09G 2310/0251; G02F 1/13452; G02F 1/136286; G09G 2300/0823; G02F 1/1368

(57) ABSTRACT

The disclosure discloses an array substrate, a method for driving the same and a display device. The array substrate includes: a plurality of pixel elements, all pixel elements in each column being connected on two data lines and two gate lines, each pixel element in each column is electrically connected with a first data line through a first switch transistor and electrically connected with a second data line through a second switch transistor; all gates of first switch transistors connected with respective pixel elements in each row are connected on a first gate line, all gates of second switch transistors connected with the respective pixel elements in each row are connected on a second gate line; and a first data line and a second data line shared by each column are located respectively on two sides of said column and have drive voltage with opposite polarities and equal amplitudes.

### CROSS-REFERENCE TO RELATED APPLICATION

This Application claims priority to Chinese Patent Application No. 201710729162.2, filed on Aug. 23, 2017, the content of which is incorporated by reference in the entirety.

### TECHNICAL FIELD

This disclosure relates to the field of display technologies, and particularly to an array substrate, a method for driving the same and a display device.

### DESCRIPTION OF RELATED ART

In a Thin Film Transistor-Liquid Crystal Display (TFT-LCD) device in the related art, a data signal is output by a drive chip onto a data line to charge each pixel element through a switch transistor. And in a traditional design of an array substrate, a pixel element is provided with a signal via one data line, and charged, and since there are inevitable capacitor and resistor loads on the data line, there may be a delay before the signal on the data line reaches expected voltage, where a magnitude of the delay is determined by magnitudes of the capacitor and resistor loads, so the pixel element is typically charged for an actual period of time shorter than an ideal charging period of time.

Also in order to prevent liquid crystals from being polarized, the voltage on each pixel element shall invert its polarity, thus the signal on the data line shall also invert its polarity. For example, the positive and negative voltage of the signal on the data line is ±5V, and when the polarity is inverted, the charging voltage is changed by 10V, the large voltage change will further lengthen the magnitude of the delay of the signal on the data line, thus the charging period of time will be further shortened. While as the resolution of the display device becomes higher and higher, the period of time for charging each pixel element becomes shorter and shorter, so there is a higher and higher requirement on the charging period of time. If there is a too long delay of the signal on the data line, then the pixel element may be charged sufficiently, so the pixel element cannot reach the expected voltage, and an image may be displayed on the display device in abnormal color.

In summary, in the TFT-LCD display device in the related art, each pixel element is provided with a signal via one data line, and charged, and the polarity of the voltage on the pixel element is inverted while the pixel element is being charged, so there is such a long delay on the data line that may shorten the period of time for charging the pixel element.

### SUMMARY

Embodiments of the disclosure provide an array substrate, a method for driving the same and a display device.

In an aspect, the embodiments of the disclosure provide an array substrate including: a plurality of pixel elements arranged in an array, all pixel elements in each column of pixel elements being connected on two data lines shared by said column of pixel elements, and all pixel elements in each row of pixel elements being connected onto two gate lines shared by said row of pixel elements, wherein: each pixel element in each column of pixel elements is electrically connected with a first data line of the two data lines shared by said column of pixel elements respectively through a first switch transistor, and is electrically connected with a second data line of the two data lines shared by said column of pixel elements respectively through a second switch transistor; all gates of first switch transistors connected with respective pixel elements in each row of pixel elements are connected on a first gate line of the two gate lines shared by said row of pixel elements, and all gates of second switch transistors connected with the respective pixel elements in each row of pixel elements are connected on a second gate line of the two gate lines shared by said row of pixel elements; and a first data line and a second data line shared by each column of pixel elements are located respectively on two sides of said column of pixel elements, and drive voltage on the first data line and the second data line shared by said column of pixel elements have opposite polarities and equal amplitudes.

In some embodiment, both a first gate line and a second gate line shared by each row of pixel elements are located on a same side of said row of pixel elements.

In some embodiment, drive voltage on two data lines between two adjacent columns of pixel elements has a same polarity.

In some embodiment, each first data line is electrically connected with a drive chip through a third switch transistor, and all gates of third switch transistors corresponding to respective first data lines are electrically connected on a first signal line; wherein the first signal line is configured to provide the third switch transistors with a turn-on signal.

In some embodiment, each second data line is electrically connected with a drive chip through a fourth switch transistor, and all gates of fourth switch transistors corresponding to respective second data lines are electrically connected on a second signal line; wherein the second signal line is configured to provide the fourth switch transistors with a turn-on signal.

In some embodiment, the drive chip is configured to provide the first data line and the second data line shared by each column of pixel elements with drive voltage with opposite polarities and equal amplitudes.

In some embodiment, the drive chip is configured to provide the first data line and the second data line shared by each column of pixel elements with drive voltage with opposite polarities and equal amplitudes.

In another aspect, the embodiments of the disclosure provide a display device including an array substrate, the array substrate includes: a plurality of pixel elements arranged in an array, all pixel elements in each column of pixel elements being connected on two data lines shared by said column of pixel elements, and all pixel elements in each row of pixel elements being connected onto two gate lines shared by said row of pixel elements, wherein: each pixel element in each column of pixel elements is electrically connected with a first data line of the two data lines shared by said column of pixel elements respectively through a first switch transistor, and is electrically connected with a second data line of the two data lines shared by said column of pixel elements respectively through a second switch transistor; all gates of first switch transistors connected with respective pixel elements in each row of pixel elements are connected on a first gate line of the two gate lines shared by said row of pixel elements, and all gates of second switch transistors connected with the respective pixel elements in each row of pixel elements are connected on a second gate line of the two gate lines shared by said row of pixel elements; and a first data line and a second data line shared by each column of pixel elements are located respectively on two sides of said column of pixel elements, and drive voltage on the first data line and the second data line shared by said column of pixel elements have opposite polarities and equal amplitudes.

In some embodiment, both a first gate line and a second gate line shared by each row of pixel elements are located on a same side of said row of pixel elements.

In some embodiment, drive voltage on two data lines between two adjacent columns of pixel elements has a same polarity.

In some embodiment, each first data line is electrically connected with a drive chip through a third switch transistor, and all gates of third switch transistors corresponding to respective first data lines are electrically connected on a first signal line; wherein the first signal line is configured to provide the third switch transistors with a turn-on signal.

In some embodiment, each second data line is electrically connected with a drive chip through a fourth switch transistor, and all gates of fourth switch transistors corresponding to respective second data lines are electrically connected on a second signal line; wherein the second signal line is configured to provide the fourth switch transistors with a turn-on signal.

In some embodiment, the drive chip is configured to provide the first data line and the second data line shared by each column of pixel elements with drive voltage with opposite polarities and equal amplitudes.

In some embodiment, the drive chip is configured to provide the first data line and the second data line shared by each column of pixel elements with drive voltage with opposite polarities and equal amplitudes.

In still another aspect, the embodiments of the disclosure provide a method for driving the array substrate above according to the embodiments of the disclosure, the method including: outputting a first periodic pulse signal on all first data lines, outputting a turn-on signal with a first length of time on a first gate line connected with at least one row of pixel elements, and when first switch transistors electrically connected with the first gate line that connected with the at least one row of pixel elements are turned on, charging the at least one row of pixel elements for a first time through first switch transistors that are turned on; and after charging for the first time is finished, outputting a second periodic pulse signal on all second data lines, outputting a turn-on signal with a second length of time on a second gate line connected with the at least one row of pixel elements, and when second switch transistors electrically connected with the second gate line that connected with the at least one row of pixel elements are turned on, charging the at least one row of pixel elements for a second time through second switch transistors that are turned on; wherein, both pulse periodicities and pulse amplitudes of the first periodic pulse signal and the second periodic pulse signal are equal to each other; one of the first periodic pulse signal and the second periodic pulse signal is a positive pulse signal, and the other is a negative pulse signal; and the first length of time is equal to the second length of time, and both of them are equal to half a pulse period.

In some embodiments, outputting the first periodic pulse signal on all the first data lines includes: outputting a third periodic pulse signal on a first signal line; and when third switch transistors electrically connected with the first signal line are turned on, outputting, by a drive chip, the first periodic pulse signal to corresponding first data lines through respective third switch transistors.

In some embodiments, outputting the second periodic pulse signal on all the second data lines includes: outputting a fourth periodic pulse signal on a second data line; and when fourth switch transistors electrically connected with the second signal line are turned on, outputting, by the drive chip, the second periodic pulse signal on corresponding second data lines through respective fourth switch transistors; wherein both pulse periodicities and pulse amplitudes of the third periodic pulse signal and the fourth periodic pulse signal are equal to each other, and both the third periodic pulse signal and the fourth periodic pulse signal are pulse signals at opposite high and low levels in a same half of a pulse period.

### BRIEF DESCRIPTION OF THE DRAWINGS

In order to make the technical solutions according to embodiments of the disclosure more apparent, the drawings to which a description of the embodiments refers will be briefly introduced below, and apparently the drawings to be described below are merely illustrative of some of the embodiments of the disclosure, and those ordinarily skilled in the art can derive from these drawings other drawings without any inventive effort.

FIG. 1 is a schematic diagram of a general structure of an array substrate according to the embodiments of the disclosure;

FIG. 2 is a flow chart of operations in a method for driving an array substrate according to the embodiments of the disclosure;

FIG. 3A is a schematic diagram of voltage signals on two data lines and a pixel element according to the embodiments of the disclosure; and

FIG. 3B is a schematic diagram of voltage signals on a first signal line and a second signal line according to the embodiments of the disclosure.

### DETAILED DESCRIPTION OF THE EMBODIMENTS

The technical solutions according to embodiments of the disclosure will be described below clearly and fully with reference to the drawings in the embodiments of the disclosure, and apparently the embodiments to be described are only a part but not all of the embodiments of the disclosure. Based upon the embodiments here of the disclosure, all the other embodiments which can occur to those ordinarily skilled in the art without any inventive effort shall fall into the scope of the disclosure.

Here the sizes of components, and the shapes of areas in the drawings are not intended to reflect any real proportions thereof, but only intended to illustrate the disclosure of the disclosure.

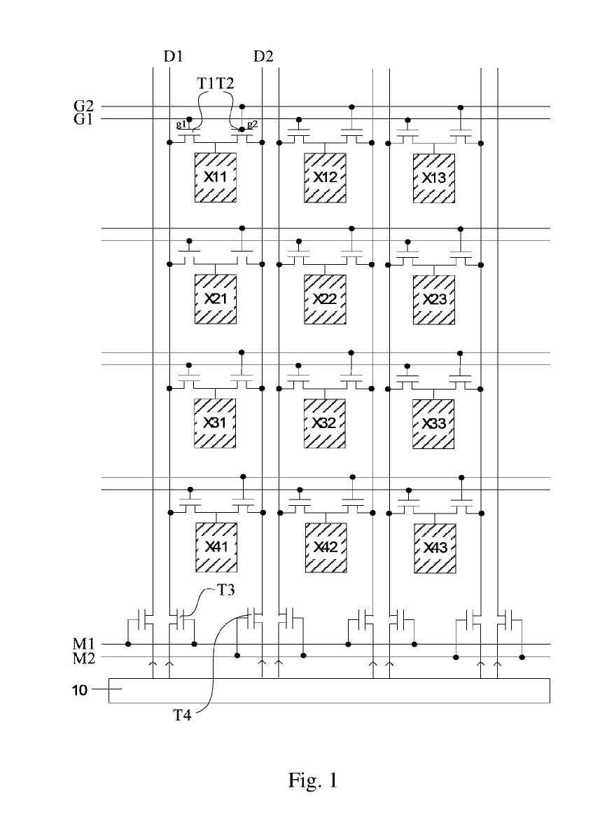

Embodiments of the disclosure provide an array substrate, as illustrated in FIG. 1 which is a schematic structural diagram of a general structure of the array substrate according to the embodiments of the disclosure, the array substrate includes a plurality of pixel elements arranged in an array, all pixel elements in each column of pixel elements being connected on two data lines shared by said column of pixel elements, and all pixel elements in each row of pixel elements being connected onto two gate lines shared by said row of pixel elements, wherein: each pixel element in each column of pixel elements is electrically connected with a first data line of the two data lines shared by said column of pixel elements respectively through a first switch transistor, and is electrically connected with a second data line of the two data lines shared by said column of pixel elements respectively through a second switch transistor; all gates of first switch transistors connected with respective pixel elements in each row of pixel elements are connected on a first gate line of the two gate lines shared by said row of pixel elements, and all gates of second switch transistors connected with the respective pixel elements in each row of pixel elements are connected on a second gate line of the two gate lines shared by said row of pixel elements; and a first data line and a second data line shared by each column of pixel elements are located respectively on two sides of said column of pixel elements, and drive voltage on the first data line and the second data line shared by said column of pixel elements have opposite polarities and equal amplitudes.

For the sake of a convenient description, there are illustrated only pixel elements arranged in an array of four rows by three columns in the embodiments of the disclosure, but the embodiments of the disclosure will not be limited thereto. Since each pixel element is connected likewise, for the sake of a convenient description, a pixel element X11 will be described in details in the embodiments of the disclosure, and the same description will apply to the other pixel elements.

In the array substrate according to the embodiments of the disclosure, all the pixel elements in each column of pixel elements are connected on two data lines, and for example, all the pixel elements X11, X21, X31, and X41 in a first column of pixel elements in FIG. 1 are connected on a first data line D1 and a second data line D2; and all the pixel elements in each row of pixel elements are connected on two gate lines, and for example, all the pixel elements X11, X12, and X13 in a first row of pixel elements are connected on a first gate line G1 and a second gate line G2.

Each pixel element in each column of pixel elements is electrically connected with a first data line respectively through a first switch transistor; and for example, the pixel element X11 in the first column of pixel elements in FIG. 1 is electrically connected with the first data line D1 through a first switch transistor T1. Correspondingly each pixel element in each column of pixel elements is also electrically connected with a second data line respectively through a second switch transistor; and for example, the pixel element X11 in the first column of pixel elements in FIG. 1 is electrically connected with the second data line D2 through a second switch transistor T2. Since there are opposite polarities of drive voltage on the two data lines, the first data line and the second data line can be arranged respectively on two sides of each column of pixel elements in order to alleviate coupling them.

Since each pixel element in each column of pixel elements is electrically connected respectively with two data lines (the first data line D1 and the second data line D2) through two switch transistors (the first switch transistor T1 and the second switch transistor T2), and there are opposite polarities and equal amplitudes of drive voltage on the two data lines, each pixel element can be charged respectively with the different polarities, that is, positive voltage is provided on one of the two data lines, and negative voltage is provided on the other data line.

Furthermore a gate of a first switch transistor connected with each pixel element in each row of pixel elements is connected on a first gate line; and for example, a gate g1 of the first switch transistor T1 of the pixel element X11 in the first row of pixel elements in FIG. 1 is electrically connected on the first gate line G1. Correspondingly a gate of a second switch transistor connected with each pixel element in each row of pixel elements is connected on a second gate line; and for example, a gate g2 of the second switch transistor T2 of the pixel element X11 in the first row of pixel elements in FIG. 1 is electrically connected on the second gate line G2.

Since all the pixel elements in each row of pixel elements are connected on two gate lines (the first gate line G1 and the second gate line G2) that are connected respectively with two switch transistors (the first switch transistor T1 and the second switch transistor T2) on the respective pixel elements, the two data lines can be controlled respectively via the two gate lines so that the pixel elements are provided with positive voltage via one of the data lines, and negative voltage via the other data line all the time.

In summary, since the polarity of the voltage on each data line in the embodiments of the disclosure can remain unchanged instead of being inverted all the time, a delay on each data line can be halved, and an actual period of time for charging each pixel element can be lengthened, as compared with the related art in which each pixel element is charged via one data line.

For example, the positive and negative voltage of the signal on the data line is ±5V, in the related art in which each pixel element is charged via one data line, the voltage on each data line shall be inverted, and changed in amplitude by 10V; the large voltage change will further lengthen the magnitude of the delay of the signal on the data line, thus further shorten the charging period of time of each pixel element. While in the embodiments of the disclosure, the pixel element can be provided with positive voltage via one of the data lines, and negative voltage via the other data line, the voltage on each data line can remain unchanged in polarity all the time, but will be only changed in amplitude by 5V, so accordingly a delay on each data line can be halved, and an actual period of time for charging each pixel element can be lengthened.

In some embodiments, positions of the two gate lines shared by each row of pixel elements can be set as needed, and they may be arranged on the same side of said row of pixel elements, or may be arranged on two sides of said row of pixel elements like the data lines. In some embodiments, both the first gate line and the second gate line connected with each row of pixel elements are located on the same side of said row of pixel elements.

For each column of pixel elements, the two data lines connected with all the pixel elements of said column of pixel elements are arranged respectively on two sides of said column of pixel elements. And for the entire array substrate, there are two data lines arranged between two adjacent columns of pixel elements, and corresponding respectively to the two adjacent columns of pixel elements; and in order to alleviate coupling between the two data lines, in some embodiments, there is the same polarity of drive voltage on the two data lines located between the two adjacent columns of pixel elements.

In some embodiments, in order to better control the pixel elements to be charged, a switch transistor is arranged on each data line.

In some embodiments, each first data line is electrically connected with a drive chip through a third switch transistor, and all gates of third switch transistors corresponding to respective first data lines are electrically connected on a first signal line; wherein the first signal line is configured to provide the third switch transistors with a turn-on signal.

For example, the first data line D1 in FIG. 1 is electrically connected with a drive chip 10 through a third switch transistor T3. A gate g3 of the third switch transistor T3 corresponding to the first data line D1 in FIG. 1 is electrically connected on a first signal line M1. The first signal line M1 is configured to provide all the switch transistors connected therewith with a turn-on signal, where the turn-on signal is a periodic pulse signal alternately at high and low levels, and the amplitude of the periodic pulse signal alternately at the high and low levels is generally set according to the characteristic of the switch transistor; and for example, the low voltage is VGL of generally −8V, and the high voltage is VGH of generally 10V to 33V, in an LCD.

Correspondingly each second data line is electrically connected with the drive chip through a fourth switch transistor, and all gates of fourth switch transistors corresponding to respective second data lines are electrically connected on a second signal line; wherein the second signal line is configured to provide the fourth switch transistors with a turn-on signal.

For example, the second data line D2 in FIG. 1 is electrically connected with the drive chip 10 through a fourth switch transistor T4. A gate g4 of the fourth switch transistor T4 corresponding to the second data line D2 in FIG. 1 is electrically connected on a second signal line M2, the second signal line M2 is configured to provide all the switch transistors connected therewith with a turn-on signal, where the turn-on signal is a periodic pulse signal alternately at high and low levels, and the amplitude of the periodic pulse signal alternately at the high and low levels is generally set according to the characteristic of the switch transistor; and for example, the low voltage is VGL of generally −8V, and the high voltage is VGH of generally 10V to 33V, in an LCD.

Where the drive chip above can be selected as needed, in some embodiments, the drive chip is configured to provide the first data line and the second data line shared by each column of pixel elements with drive voltage with opposite polarities and equal amplitudes. For example, a rectangular pulse signal can be output from the drive chip, or the positive and negative voltage can be driven in a mode-adjusting manner.

Based upon the same inventive concept, the embodiments of the disclosure further provide a display device including the array substrate above according to the embodiments of the disclosure. Reference can be made to the embodiments of the array substrate an implementation of the display device, so a repeated description thereof will be omitted here.

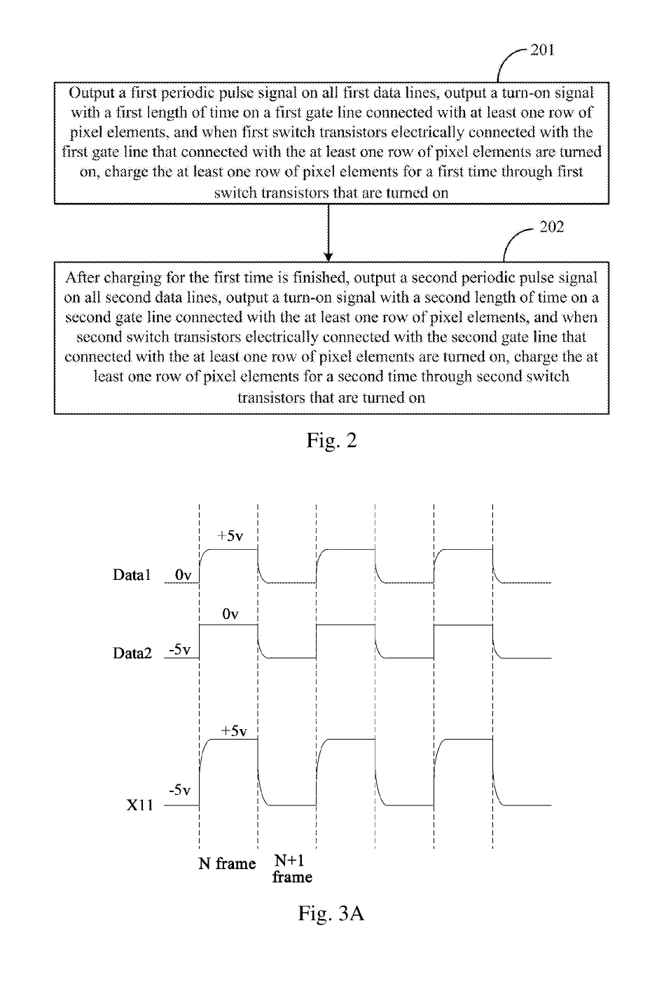

Based upon the same inventive concept, the embodiments of the disclosure further provide a method for driving the array substrate above according to the embodiments of the disclosure, and as illustrated in FIG. 2 which is a flow chart of operations in a method for driving the array substrate according to the embodiments of the disclosure, the method includes the following operations.

The operation 201 is to output a first periodic pulse signal on all first data lines, to output a turn-on signal with a first length of time on a first gate line connected with at least one row of pixel elements, and when first switch transistors electrically connected with the first gate line that connected with the at least one row of pixel elements are turned on, to charge the at least one row of pixel elements for a first time through first switch transistors that are turned on.

The operation 202 is, after charging for the first time is finished, to output a second periodic pulse signal on all second data lines, to output a turn-on signal with a second length of time on a second gate line connected with the at least one row of pixel elements, and when second switch transistors electrically connected with the second gate line that connected with the at least one row of pixel elements are turned on, to charge the at least one row of pixel elements for a second time through second switch transistors that are turned on.

Where there are equal pulse periodicities and equal pulse amplitudes of the first periodic pulse signal and the second periodic pulse signal; one of the first periodic pulse signal and the second periodic pulse signal is a positive pulse signal, and the other periodic pulse signal is a negative pulse signal; and the first length of time is equal to the second length of time, and both of them are equal to half a pulse period.

In a particular implementation, each pixel element is charged alike, so only the pixel element X11 in FIG. 1 will be described here by way of an example, and the same description will apply to the other pixel elements.

If the pixel element X11 is required to be charged firstly positively and then negatively for the same length of time, then firstly a periodic positive pulse signal Data1 is output on the first data line D1, and also a high-level signal with the first length of time is output on the first gate line G1; and when the first switch transistor T1 electrically connected with the first gate line G1 is turned on, the pixel element X11 can be charged positively through the first switch transistor T1.

After positive charging is finished, a periodic positive pulse signal Data2 is output on the second data line D2, and also a high-level signal with the second length of time is output on the second gate line G2; and when the second switch transistor T2 electrically connected with the second gate line G2 is turned on, the pixel element X11 can be charged positively through the second switch transistor T2.

In some embodiments, outputting the first periodic pulse signal on all the first data lines includes: outputting a third periodic pulse signal on a first signal line; and when third switch transistors electrically connected with the first signal line are turned on, outputting, by a drive chip, the first periodic pulse signal to corresponding first data lines through respective third switch transistors.

In some embodiments, a pulse signal at high and low levels V1 is output on the first signal line M1, where V1 is also a periodic pulse signal, which remains at a high level for one half of a pulse period, and a low level for the other half of the pulse period; and the third switch transistor T3 is turned on at a high level, and at this time, the drive chip 10 can output the positive pulse signal Data1 on the first data line D1 through the third switch transistor T3.

In some embodiments, outputting the second periodic pulse signal on all the second data lines includes: outputting a fourth periodic pulse signal on a second data line; and when fourth switch transistors electrically connected with the second signal line are turned on, outputting, by the drive chip, the second periodic pulse signal on corresponding second data lines through respective fourth switch transistors; where there are equal pulse periodicities and equal pulse amplitudes of the third periodic pulse signal and the fourth periodic pulse signal, and both the third periodic pulse signal and the fourth periodic pulse signal are pulse signals at opposite high and low levels in the same half of a pulse period.

In some embodiments, a pulse signal at high and low levels V2 is output on the second signal line M2, where V2 is also a periodic pulse signal, which remains at a high level for one half of a pulse period, and a low level for the other half of the pulse period; and the fourth switch transistor T4 is turned on at a high level, and at this time, the drive chip 10 can output the negative pulse signal Data2 on the second data line D2 through the fourth switch transistor T4.

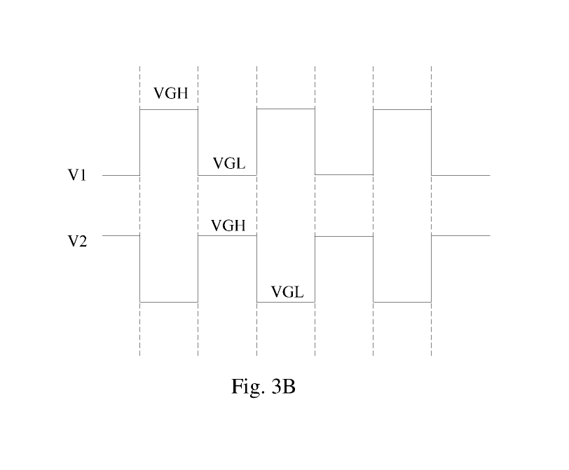

As illustrated in FIG. 3A and FIG. 3B, FIG. 3A is a schematic diagram of voltage signals on two data lines and a pixel element according to the embodiments of the disclosure; and FIG. 3B is a schematic diagram of voltage signals on a first signal line and a second signal line according to the embodiments of the disclosure, where both the pulse periodicities and the pulse amplitudes of the positive pulse signal Data1 and the negative pulse signal Data2 are equal to each other; and the both the pulse periodicities and the pulse amplitudes of the pulse signal V1 and the pulse signal V2 are also equal to each other.

In some embodiments, while the N-th frame is being displayed, the pulse signal at high and low levels V1 at a high level is output on the first signal line M1, the third switch transistor T3 is turned on, and the drive chip 10 can output the positive pulse signal Data1 on the first data line D1 through the third switch transistor T3 to charge positively the pixel element X11.

While the (N+1)-th frame is being displayed, the pulse signal at high and low levels V2 at a high level is output on the second signal line M2, the fourth switch transistor T4 is turned on, and the drive chip 10 can output the negative pulse signal Data2 on the second data line D2 through the fourth switch transistor T4 to charge negatively the pixel element X11.

In some embodiments, in order to enable each pixel element to be charged positively and negatively in two separate processes, both the pulse signal V1 and the pulse signal V2 are pulse signals at high and low levels, and have opposite high and low levels in the same half of a pulse period, thus the third switch transistor T3 and the fourth switch transistor T4 can be turned on and off periodically. Also in order to enable each pixel element to charged positively and negatively for equal lengths of time, the first length of time for charging for the first time is set equal to the second length of time for charging for the second time, and both of them are equal to the half of a pulse period corresponding to the pulse signal (Data1, Data2, V1, or V2).

Furthermore for the entire array substrate, each row of pixel elements can be controlled separately, so which one of the rows of pixel elements to be firstly charged, and whether one or more rows of pixel elements is or are to be charged concurrently can be set as needed, although the embodiments of the disclosure will not be limited thereto.

Here in the embodiments of the disclosure, all the switch transistors are N-type switch transistors as described above by way of an example, but the embodiments of the disclosure will not be limited in practical thereto, and they can all be P-type switch transistors, or can include both N-type and P-type switch transistors, as long as a turn-on signal is modified according to the characteristic of a switch transistor.

In summary, in the array substrate, the method for driving the same, and the display device according to the embodiments of the disclosure, since each pixel element in each column of pixel elements is electrically connected respectively with two data lines through two switch transistors, and there are opposite polarities and equal amplitudes of drive voltage on the two data lines, each pixel element can be charged respectively with the different polarities; and since all the pixel elements in each row of pixel elements are also connected on two gate lines connected respectively with the two switch transistors on each pixel element, the two data lines can be controlled respectively via the two gate lines so that the pixel elements are provided with positive voltage via one of the data lines, and negative voltage via the other data line all the time. Since the polarity of the voltage on a data line in the embodiments of the disclosure can remain unchanged instead of being inverted all the time, a delay on the data line can be halved, and an actual period of time for charging each pixel element can be lengthened, as compared with the related art in which each pixel element is charged via one data line.

Evidently those skilled in the art can make various modifications and variations to the disclosure without departing from the spirit and scope of the disclosure. Thus the disclosure is also intended to encompass these modifications and variations thereto so long as the modifications and variations come into the scope of the claims appended to the disclosure and their equivalents.

1. An array substrate, comprising: a plurality of pixel elements arranged in an array, all pixel elements in each column of pixel elements being connected on two data lines shared by said column of pixel elements, and all pixel elements in each row of pixel elements being connected onto two gate lines shared by said row of pixel elements, wherein:
each pixel element in each column of pixel elements is electrically connected with a first data line of the two data lines shared by said column of pixel elements respectively through a first switch transistor, and is electrically connected with a second data line of the two data lines shared by said column of pixel elements respectively through a second switch transistor;
all gates of first switch transistors connected with respective pixel elements in each row of pixel elements are connected on a first gate line of the two gate lines shared by said row of pixel elements, and all gates of second switch transistors connected with the respective pixel elements in each row of pixel elements are connected on a second gate line of the two gate lines shared by said row of pixel elements; and
a first data line and a second data line shared by each column of pixel elements are located respectively on two sides of said column of pixel elements, and drive voltage on the first data line and the second data line shared by said column of pixel elements have opposite polarities and equal amplitudes.

2. The array substrate according to claim 1, wherein both a first gate line and a second gate line shared by each row of pixel elements are located on a same side of said row of pixel elements.

3. The array substrate according to claim 1, wherein drive voltage on two data lines between two adjacent columns of pixel elements has a same polarity.

4. The array substrate according to claim 1, wherein each first data line is electrically connected with a drive chip through a third switch transistor, and all gates of third switch transistors corresponding to respective first data lines are electrically connected on a first signal line; wherein the first signal line is configured to provide the third switch transistors with a turn-on signal.

5. The array substrate according to claim 1, wherein each second data line is electrically connected with a drive chip through a fourth switch transistor, and all gates of fourth switch transistors corresponding to respective second data lines are electrically connected on a second signal line; wherein the second signal line is configured to provide the fourth switch transistors with a turn-on signal.

6. The array substrate according to claim 4, wherein the drive chip is configured to provide the first data line and the second data line shared by each column of pixel elements with drive voltage with opposite polarities and equal amplitudes.

7. The array substrate according to claim 5, wherein the drive chip is configured to provide the first data line and the second data line shared by each column of pixel elements with drive voltage with opposite polarities and equal amplitudes.

8. A display device, comprising an array substrate, wherein the array substrate comprises: a plurality of pixel elements arranged in an array, all pixel elements in each column of pixel elements being connected on two data lines shared by said column of pixel elements, and all pixel elements in each row of pixel elements being connected onto two gate lines shared by said row of pixel elements, wherein:
each pixel element in each column of pixel elements is electrically connected with a first data line of the two data lines shared by said column of pixel elements respectively through a first switch transistor, and is electrically connected with a second data line of the two data lines shared by said column of pixel elements respectively through a second switch transistor;
all gates of first switch transistors connected with respective pixel elements in each row of pixel elements are connected on a first gate line of the two gate lines shared by said row of pixel elements, and all gates of second switch transistors connected with the respective pixel elements in each row of pixel elements are connected on a second gate line of the two gate lines shared by said row of pixel elements; and
a first data line and a second data line shared by each column of pixel elements are located respectively on two sides of said column of pixel elements, and drive voltage on the first data line and the second data line shared by said column of pixel elements have opposite polarities and equal amplitudes.

9. The display device according to claim 8, wherein both a first gate line and a second gate line shared by each row of pixel elements are located on a same side of said row of pixel elements.

10. The display device according to claim 8, wherein drive voltage on two data lines between two adjacent columns of pixel elements has a same polarity.

11. The display device according to claim 8, wherein each first data line is electrically connected with a drive chip through a third switch transistor, and all gates of third switch transistors corresponding to respective first data lines are electrically connected on a first signal line; wherein the first signal line is configured to provide the third switch transistors with a turn-on signal.

12. The display device according to claim 8, wherein each second data line is electrically connected with a drive chip through a fourth switch transistor, and all gates of fourth switch transistors corresponding to respective second data lines are electrically connected on a second signal line; wherein the second signal line is configured to provide the fourth switch transistors with a turn-on signal.

13. The display device according to claim 11, wherein the drive chip is configured to provide the first data line and the second data line shared by each column of pixel elements with drive voltage with opposite polarities and equal amplitudes.

14. The display device according to claim 12, wherein the drive chip is configured to provide the first data line and the second data line shared by each column of pixel elements with drive voltage with opposite polarities and equal amplitudes.

15. A method for driving the array substrate according to claim 1, the method comprising:
outputting a first periodic pulse signal on all first data lines, outputting a turn-on signal with a first length of time on a first gate line connected with at least one row of pixel elements, and when first switch transistors electrically connected with the first gate line that connected with the at least one row of pixel elements are turned on, charging the at least one row of pixel elements for a first time through first switch transistors that are turned on; and
after charging for the first time is finished, outputting a second periodic pulse signal on all second data lines, outputting a turn-on signal with a second length of time on a second gate line connected with the at least one row of pixel elements, and when second switch transistors electrically connected with the second gate line that connected with the at least one row of pixel elements are turned on, charging the at least one row of pixel elements for a second time through second switch transistors that are turned on;
wherein, both pulse periodicities and pulse amplitudes of the first periodic pulse signal and the second periodic pulse signal are equal to each other; one of the first periodic pulse signal and the second periodic pulse signal is a positive pulse signal, and the other is a negative pulse signal; and the first length of time is equal to the second length of time, and both of them are equal to half a pulse period.

16. The method according to claim 15, wherein outputting the first periodic pulse signal on all the first data lines comprises:
outputting a third periodic pulse signal on a first signal line; and when third switch transistors electrically connected with the first signal line are turned on, outputting, by a drive chip, the first periodic pulse signal to corresponding first data lines through respective third switch transistors.

17. The method according to claim 16, wherein outputting the second periodic pulse signal on all the second data lines comprises:
outputting a fourth periodic pulse signal on a second data line; and when fourth switch transistors electrically connected with the second signal line are turned on, outputting, by the drive chip, the second periodic pulse signal on corresponding second data lines through respective fourth switch transistors;
wherein both pulse periodicities and pulse amplitudes of the third periodic pulse signal and the fourth periodic pulse signal are equal to each other, and both the third periodic pulse signal and the fourth periodic pulse signal are pulse signals at opposite high and low levels in a same half of a pulse period.
